(19) United States
(12) Patent Application Publication
(10) Pub. No.: US 2016/0225706 A1
(43) Pub. Date: Aug. 4, 2016

(54) PRINTED CIRCUIT BOARD, SEMICONDUCTOR PACKAGE AND METHOD OF MANUFACTURING THE SAME

(71) Applicant: Samsung Electro-Mechanics Co., Ltd., Suwon-si (KR)

(72) Inventors: Jung-Hyun CHO, Busan (KR); Young-Gwan KO, Seoul (KR); Il-Jong SEO, Cheongju-si (KR); Yong-Ho BAEK, Seoul (KR)

(73) Assignee: Samsung Electro-Mechanics Co., Ltd., Suwon-si (KR)

(21) Appl. No.: 15/008,247

(22) Filed: Jan. 27, 2016

(30) Foreign Application Priority Data
Feb. 3, 2015 (KR) 10-2015-0016893

(51) Int. Cl. H01L 23/498; H01L 21/48; H01L 21/683; H01L 23/00

(52) U.S. Cl. CPC H01L 23/49822; H01L 23/49827; H01L 23/49838; H01L 24/17; H01L 21/4857; H01L 21/486; H01L 21/6835; H01L 2224/16237; H01L 2221/68345; H01L 2221/68359

(57) ABSTRACT

A printed circuit board, a semiconductor package and a method of manufacturing the same are provided. The printed circuit board includes a circuit layer including a buried pad embedded on an upper surface of an insulating layer, and a groove part disposed in the buried pad.

### CROSS-REFERENCE TO RELATED APPLICATION

This application claims the benefit under 35 USC 119(a) of Korean Patent Application No. 10-2015-0016893, filed on Feb. 3, 2015, in the Korean Intellectual Property Office, the entire disclosure of which is incorporated herein by reference for all purposes.

### BACKGROUND

1. Field

The present disclosure relates to a printed circuit board, a semiconductor package and a method of manufacturing the same.

2. Description of Related Art

Structure of embedded trace substrate (ETS) is a structure used for most of thin film products since fine patterns can be implemented. However, it is not suitable for offering a fine-pitch bump due to solder bridge issues during assemblies.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a printed circuit board includes a circuit layer including a buried pad embedded on an upper surface of an insulating layer, and a groove part disposed in the buried pad.

The general aspect of the printed circuit board may further include a surface treatment layer disposed on a lower surface of the groove part.

The general aspect of the printed circuit board may further include a bumping material disposed in the groove part.

The bumping material may include solder paste.

The bumping material may include a solder ball.

The bumping material may have a protrusion part that protrudes toward an upper part of the buried pad.

The bumping material may have a recession part that recesses toward a bottom of the buried pad.

The circuit layer may include a buried pattern embedded in the upper surface of the insulating layer.

The circuit layer may include a pad disposed on a lower surface of the insulating layer.

The general aspect of the printed circuit board may further include a first solder resist layer formed on the upper surface of the insulating layer, except at an area where an element mounting part is disposed.

The general aspect of the printed circuit board may further include a second solder resist layer disposed on the lower surface of the insulating layer, the second solder resist layer including an opening to expose the pad.

In another general aspect, a semiconductor package includes a circuit layer including a printed circuit board including a circuit layer including a buried pad embedded in an upper surface of an insulating layer and a groove part formed on the buried pad, and an element mounted on the printed circuit board with a pillar bump disposed in the groove part of the printed circuit board.

The element may be mounted on the printed circuit board using a bumping material disposed in the groove part.

In another general aspect, a method of manufacturing a printed circuit board includes forming a metal pattern for a groove part on a carrier member, forming a first circuit layer comprising a buried pad that surrounds the metal pattern on the carrier member, forming an insulating layer on the carrier member to cover the first circuit layer, forming a second circuit layer comprising a pad on the insulating layer, removing the carrier member from a laminate on which the second circuit layer is formed, and forming a groove part on the buried pad by removing the metal pattern.

The general aspect of the method may further involve forming a surface treatment layer on the metal pattern after forming a metal pattern.

The general aspect of the method may further involve disposing a bumping material in the groove part after the forming of the groove part.

In yet another general aspect, a method of manufacturing a printed circuit board involves forming a bumping material on a carrier member, forming a first circuit layer comprising a buried pad that surrounds the bumping material on the carrier member, forming an insulating layer on the carrier member to cover the first circuit layer, forming a second circuit layer comprising a pad on the insulating layer, and removing the carrier member from the first circuit layer and the insulating layer.

The general aspect of the method may further involve inserting a pillar bump of an element into a groove part including the bumping material to bond the element to the buried pad.

Other features and aspects will be apparent from the following detailed description, the drawings, and the claims.

### BRIEF DESCRIPTION OF THE DRAWINGS

FIG. 1 is a sectional view illustrating an example of a printed circuit board.

FIG. 2 is a sectional view illustrating another example of a printed circuit board.

FIG. 3 is a sectional view illustrating another example of a printed circuit board.

FIG. 4 is a sectional view illustrating another example of a printed circuit board.

FIG. 5 is a sectional view illustrating another example of a printed circuit board.

FIG. 6 is a sectional view illustrating an example of a semiconductor package.

FIG. 7 is a sectional view illustrating another example of a semiconductor package.

FIG. 8 is a sectional view illustrating another example of a semiconductor package.

FIG. 9 is a front elevational view illustrating various designs of buried pads in accordance with an example of a semiconductor package.

FIG. 10 is a flowchart illustrating an example of a method for manufacturing a semiconductor package.

FIG. 11 to FIG. 28 are sectional views illustrating an example of a method for manufacturing a semiconductor package.

FIG. 29 is a flowchart illustrating another example of a method for manufacturing a semiconductor package.

FIG. 30 to FIG. 47 are sectional views illustrating another example of a method for manufacturing a semiconductor package.

FIG. 48 is a flowchart illustrating another example of a method for manufacturing a semiconductor package.

FIG. 49 to FIG. 68 are sectional views illustrating another example of a method for manufacturing a semiconductor package.

FIG. 69 is a flowchart illustrating another example of a method for manufacturing a semiconductor package.

FIG. 70 to FIG. 87 are sectional views illustrating yet another example of a method for manufacturing a semiconductor package.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Throughout the accompanying drawings, the same reference numerals are used to designate the same or similar components, and redundant descriptions thereof are omitted. Further, in the description of the present disclosure, when it is determined that the detailed description of the related art would obscure the gist of the present disclosure, the description thereof will be omitted. It will be understood that, although the terms “first,” “second,” and the like may be used herein to describe various elements, these elements should not be limited by these terms. These terms are only used to distinguish one element from another. Additionally, components of the drawings are not necessarily drawn according to their scales. For example, sizes of some components of the drawings may be exaggerated, omitted or schematically illustrated for the convenience of understanding of the present disclosure.

Hereinafter, configurations and effects of the present disclosure will be described in detail with reference to the accompanying drawings.

Printed Circuit Board

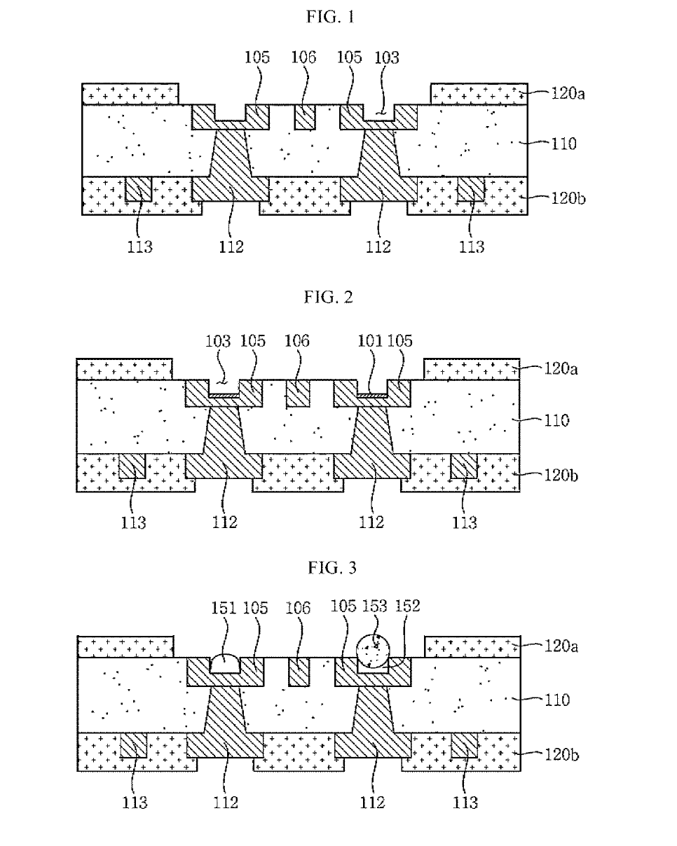

FIG. 1 illustrates a sectional view of an example of a printed circuit board.

Referring to FIG. 1, the printed circuit board includes a circuit layer including a buried pad 105 embedded in the upper surface of an insulating layer 110 and a groove part 103 formed on the buried pad 105.

The buried pad 105 may be formed to have various sectional view forms such as round, oval, polygon and the like.

The buried pad 105 includes the groove part 103 configured to hold a bumping material. A shape of the groove part 103 may be formed to correspond to a shape of the buried pad 105; however, the shape of the groove part 103 is not be limited thereto.

According to an example of the present disclosure, the assembly of an element and a board may be implemented inside the outmost layer using the buried pad 105 including the groove part 103, such that fine bump may be provided, a bump size of the element may be minimized, design freedom may be improved, and height of the entire package may be reduced due to such a bump structure. Furthermore, solder bridge issue with adjacent bumps may be minimized.

The circuit layer may include a buried pattern 106 embedded in upper surface of the insulating layer 110, a pad 112 formed on the lower surface of the insulating layer 110, and a circuit pattern 113.

A via may be also formed to electrically connect interlayers.

In FIG. 1, a double sided printed circuit board is illustrated; however, the present disclosure is not be limited thereto. A multilayer printed circuit board having 3 or more layers may be also implemented.

In this example, a first solder resist layer 120a is formed on the upper surface of the insulating layer 110, except at the area where an element mounting part is formed. A second solder resist layer 120b having an opening to expose the pad 112 is formed on the lower surface of the insulating layer 110.

The insulating layer 110 may be formed of an insulating resin that is generally used as an insulating material in printed circuit boards; however, the insulating resin material is not limited thereto. In another example, other suitable insulating material may be used to form the insulating layer 110.

According to an example of the present disclosure, the insulating layer 110 may be formed of any resin that is generally used for coreless boards. An example of the resin may include a thermosetting resin such as an epoxy resin, a thermoplastic resin such as polyimide, and a photosensitive resin; however, in another example, a different material may be used to form the insulating layer 110.

The circuit layer may be formed of a metal such as copper, aluminum and the like, which is a general metal for circuits. However, in another example, a different conductive material may be used to form the circuit layer.

The circuit layer may include a via.

The solder resist layer 120a, 120b may be in a liquid or film type.

The solder resist layer 120a, 120b is formed for protecting circuit patterns of the outmost layer and electrical insulation.

A surface treatment layer may be further selectively formed on the pad 112 that is exposed through the opening of the second solder resist layer 120b.

The surface treatment layer may be formed through, for example, electro gold plating, immersion gold plating, organic solderability preservative (OSP) or immersion tin plating, immersion silver plating, direct immersion gold plating (DIG plating), hot air solder levelling (HASL) or the like, but it may not be limited thereto.

FIG. 2 is a sectional view illustrating another example of a printed circuit board. Any description of overlapping configuration will be omitted for conciseness.

Referring to FIG. 2, the printed circuit board includes a circuit layer including a buried pad 105 embedded in the upper surface of an insulating layer 110, a groove part 103 formed on the buried pad 105, and a surface treatment layer 101 formed on the lower surface of the groove part 103.

The surface treatment layer 101 may be formed of a plating layer such as Au/Ni, Au/Pd/Ni, Au/Pd and the like. However, the material is not limited thereto.

FIGS. 3 to 5 are sectional views illustrating another example of a printed circuit board. Any description of overlapping configuration will be omitted for conciseness.

Referring to FIG. 3, the printed circuit board may include a circuit layer including a buried pad 105 embedded in the upper surface of an insulating layer 110, a groove part 103 formed on the buried pad 105, and bumping materials 151, 152, 153 formed on the groove part 103.

According to one example, the bumping material 151 may include solder paste.

According to another example, the bumping materials 152, 153 may include flux formed on the lower surface of the groove part 103 and a solder ball formed on the upper surface of the groove part 103.

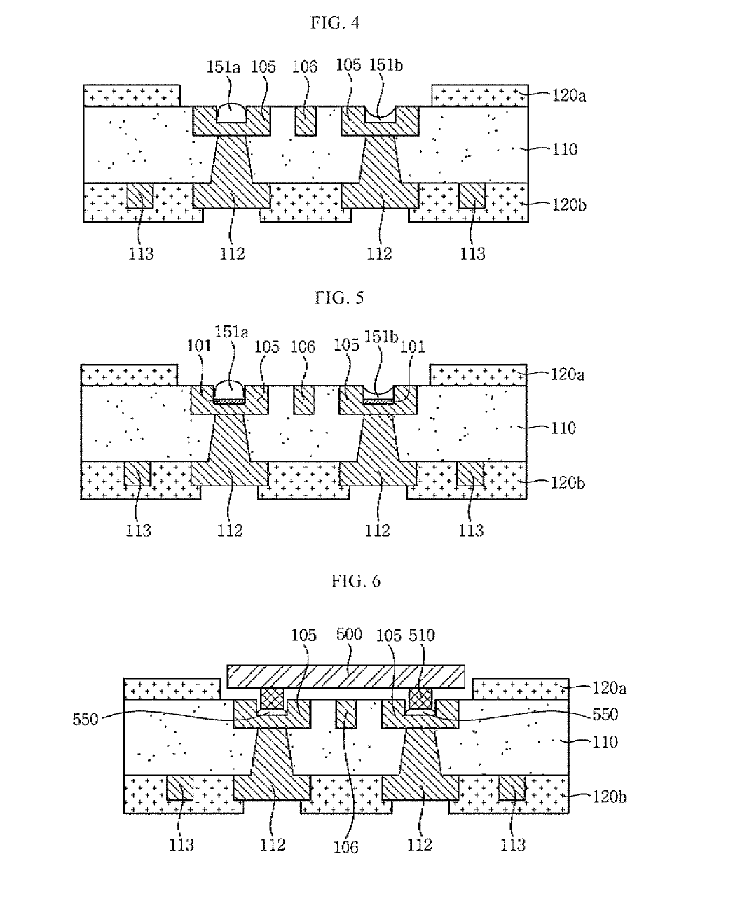

Referring to FIG. 4, the bumping material 151a is formed to have a protrusion part that protrudes toward the upper part of the buried pad 105. The bumping material 151 b is formed to have a recession part that recesses toward inside of the buried pad 105.

Referring to FIG. 5, before disposing the bumping materials 151a, 151b in the groove part 103, a surface treatment layer 101 may be formed on the lower surface of the groove part 103.

Semiconductor Package

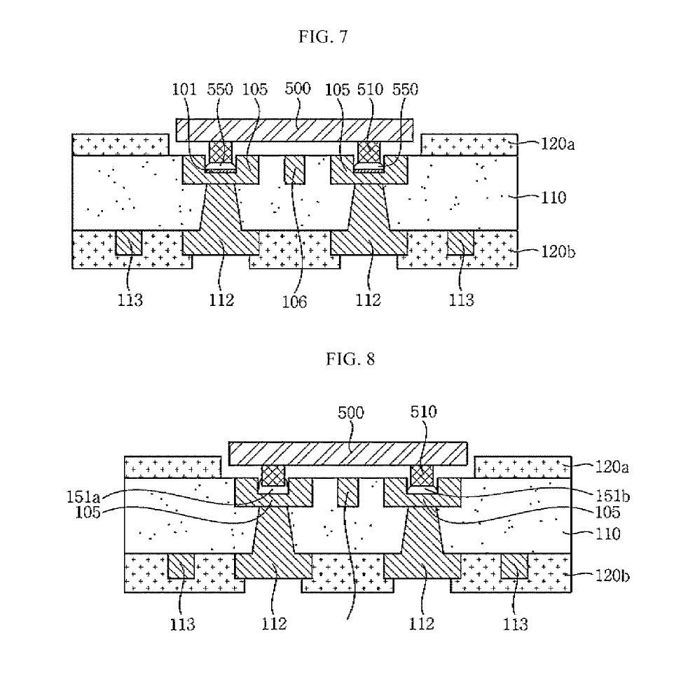

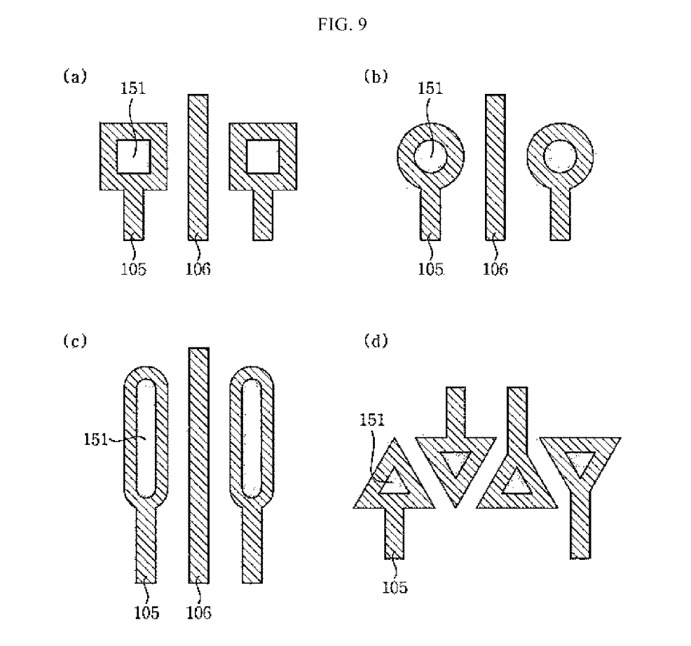

FIG. 6 is a sectional view illustrating another example of a semiconductor package. FIG. 7 is a sectional view illustrating another example of a semiconductor package. FIG. 8 is a sectional view illustrating yet another example of a semiconductor package. FIG. 9 illustrates various designs of buried pads in a semiconductor package in a front elevational view. Description of overlapping configuration will be omitted.

Referring to FIG. 6, the semiconductor package includes a printed circuit board including a circuit layer having a buried pad 105 embedded in the upper surface of an insulating layer 110 and a groove part 103 formed on the buried pad 105, and an element 500 mounted on the printed circuit board in which one end of a pillar bump 510 is disposed in the groove part 103 of the printed circuit board.

Referring to FIG. 6, a bumping material 550 is disposed on one end of the pillar bump 510 of the element 500 to be disposed on the groove part 103 of the printed circuit board. The element 500 may bond to the printed circuit board through the bumping material 550 disposed into the groove part 103.

The bumping material 550 may be a general solder ball.

Referring to FIG. 7, a surface treatment layer 101 is formed on the lower surface of the groove part 103

Referring to FIG. 8, bumping materials 151a, 151b are disposed in the groove part 103 of the printed circuit board, and one end of a pillar bump 510 of an element 500 is inserted into the groove part 103 of the printed circuit board on which the bumping materials 151a, 151b are formed.

The bumping materials 151a, 151b may have a protrusion or recession part.

The bumping materials 151a, 151b may include solder paste and/or solder ball.

Referring to FIG. 9, the buried pad 105 are formed to have various shapes in a sectional view, such as a circle, an oval, a triangle, a rectangle, a polygon and the like. A shape of the groove part 103, on which the bumping material 151 is formed, may be formed to correspond to a shape of the buried pad 105. However, the shapes of the buried pad 105 and the groove part 103 are not limited thereto.

The element 500 may include various electronic elements such as a passive element and an active element. For example, it may be any element that may be mounted on or installed inside a printed circuit board.

The element 500 may have a metal pillar bump 510 and be adhered to the buried pad 105 of the printed circuit board through the bumping materials 550, 151, 151a, 151b.

According to an example, when the groove part is formed on the buried pad to adhere the element through the bumping material that is disposed in the groove part, it may prevent the bumping material from being spread to an adjacent pattern area.

Thus, it may improve packaging properties during assembly without defects such as unbondings, bump cracks or the like and further high density circuits capable of fine-pitch may be implemented.

Method For Manufacturing Printed Circuit Board/Semiconductor Package

FIG. 10 is a flowchart illustrating an example of a method for manufacturing a semiconductor package, and FIGS. 11 to 28 are sectional views illustrating an example of a method for manufacturing a semiconductor package.

Referring to FIG. 10, the method includes preparing a carrier member (S101), forming a metal pattern (S102), forming a first circuit layer including a buried pad (S103), forming an insulating layer (S104), forming a second circuit layer (S105), eliminating the carrier member (S106), eliminating the metal pattern (S107), forming a solder resist layer (S108), and mounting an element (S109).

Hereinafter, each process will be explained with reference to sectional views illustrated in FIGS. 11 to 28.

Referring to FIG. 11, a carrier member 1000 including a first metal layer 1001 and a second metal layer 1002 is prepared.

The first metal layer 1001 may be formed of Cu; however, the material is not limited thereto.

The second metal layer 1002 may function as a seed layer and be formed of Cu.

The carrier member 1000 is provided as an example only. The carrier member 100 is used as a supporting substrate in a circuit board field, and it is configured to be eliminated or detached later. In another example, other structures that provide a support may be used.

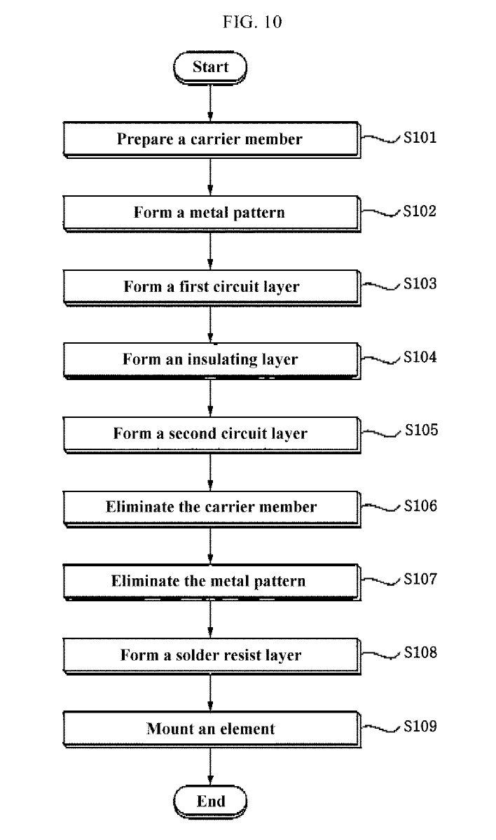

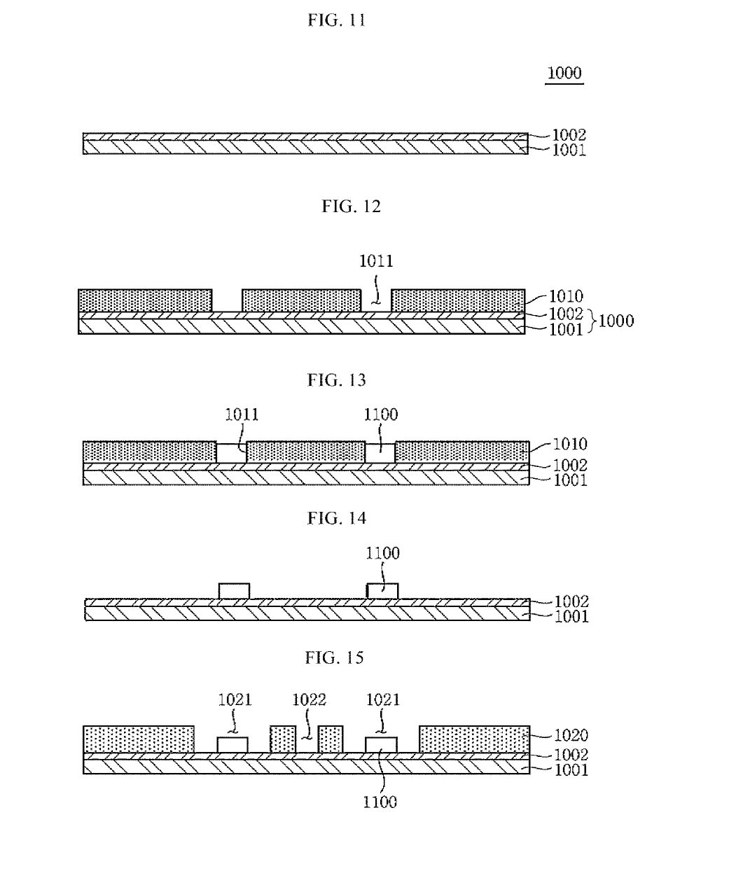

Referring to FIG. 12, a first resist pattern 1010 having a first opening 1011 is formed on the carrier member 1000.

The first opening 1011 for forming metal patterns is formed by coating a plating resist on the carrier member 1000 and performing an exposure process and a development process.

Referring to FIG. 13, a metal pattern 1100 is formed on the first opening 1011 through a plating process.

The plating process may be carried out through electrodeposition such as nickel electrodeposition and the like, except Cu electrodeposition.

Referring to FIG. 14, the resist pattern 1010 is removed.

Referring to FIG. 15, a second resist pattern 1020 having second openings 1021, 1022 is formed on the carrier member 1000.

In this example, the second opening 1021 is formed to expose the entire outside of the metal pattern 1100. A buried pad may be formed later on the second opening 1021 and a buried pattern 106 may be formed later on the second opening 1022.

Referring to FIG. 16, a first circuit layer including the buried pad 105 is formed on the carrier member 1000 within the second openings 1021, 1022 through a plating process.

The first circuit layer may include the buried pattern 106.

The plating process may be carried out through electrodeposition such as Cu electrodeposition.

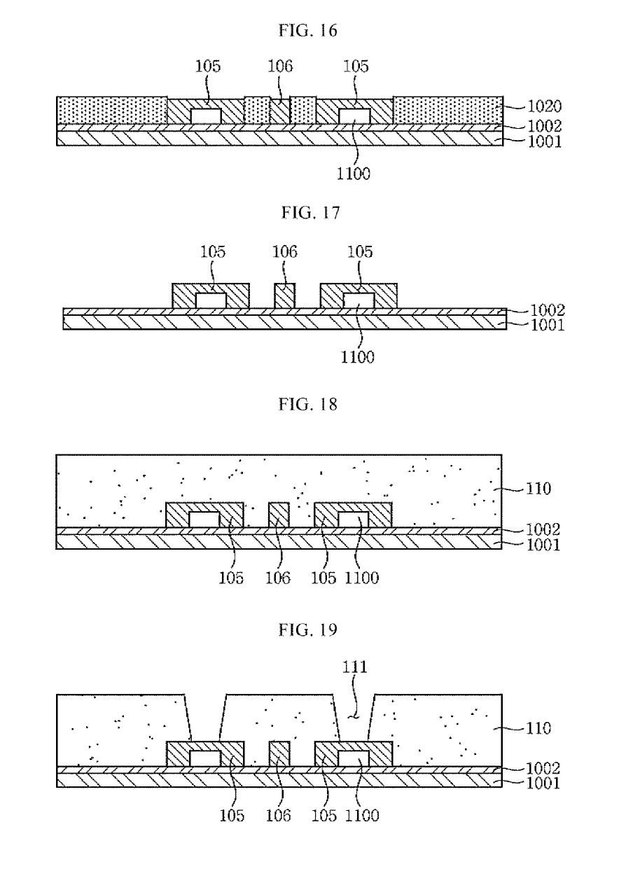

Referring to FIG. 17, the second resist pattern 1020 is eliminated.

Referring to FIG. 18, an insulating layer 110 is formed on the carrier member 1000 to cover the first circuit layer.

Referring to FIG. 19, a via hole 111 is formed in the insulating layer 110 using a laser drill. Even though it is not illustrated, a seed layer may be formed on the surface of the insulating layer 110 including the via hole 111 through an immersion plating process and the like after the via hole is formed.

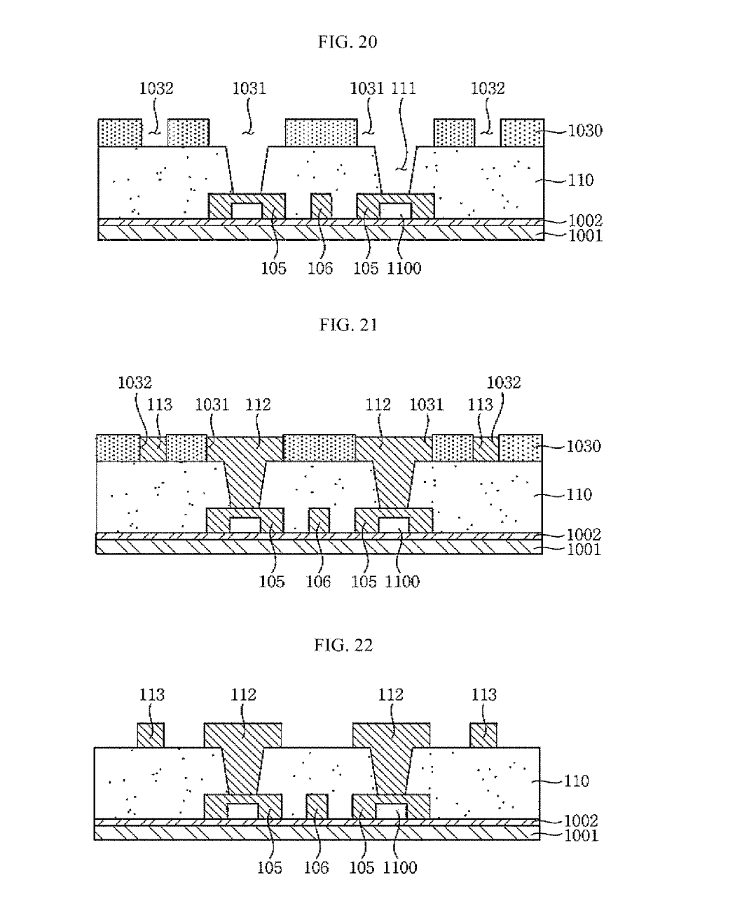

Referring to FIG. 20, a third resist pattern 1030 including third openings 1031, 1032 is formed.

A pad may be formed later in the third opening 1031, and a circuit pattern may be formed later in the third opening 1032.

Referring to FIG. 21, a second circuit layer including the pad 112 is formed in the third openings 1031, 103.

The second circuit layer includes the circuit pattern 113.

The plating process may be carried out through electrodeposition such as Cu electrodeposition.

Referring to FIG. 22, the third resist pattern 1030 is removed.

A circuit forming process is explained based on a semi additive process (SAP) in embodiments of the present disclosure but it may not be limited thereto, so that any known circuit forming process may be applied.

In addition, a multi-layer circuit board having three or more layers may be formed through the build-up process.

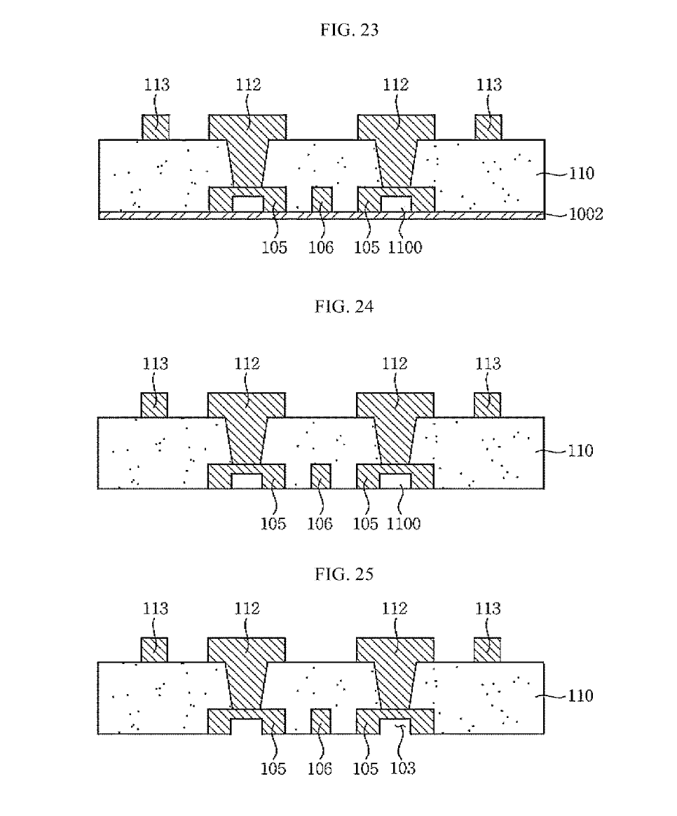

Referring to FIGS. 23 and 24, the first metal layer 1001 and the second metal layer 1002 of the carrier member are removed in order.

The removing the first metal layer 1001 and the second metal layer 1002 of the carrier member is not limited to one method; they may be removed by various methods depending on the configuration of the carrier member.

Referring to FIG. 25, the metal pattern 1100 is removed, and the groove part 103 is formed through etching and the like.

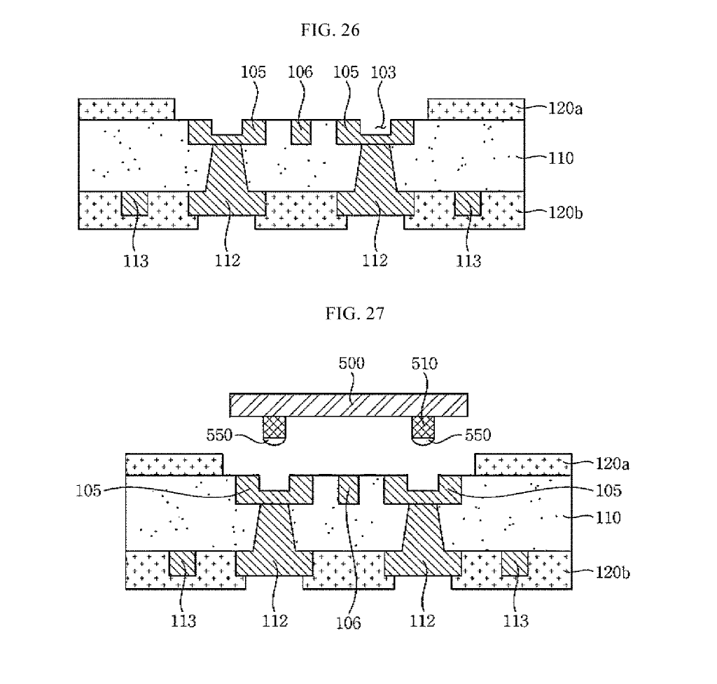

Referring to FIG. 26, solder resist layers 120a, 120b in a liquid or film type are formed as a protection layer on the outmost layer of both sides.

The solder resist layer may be formed for protecting circuit patterns of the outmost layer and electrical insulation, so that openings may be formed to expose the pad of the outmost layer that is in contact with an external component.

Referring to the example illustrated in FIG. 26, the first solder resist layer 120a is formed on the upper surface of the insulating layer 110, except at the area where an element mounting part is provided, and the second solder resist layer 120b is formed to expose the pad 112 on the lower surface of the insulating layer 110.

A surface treatment layer may be selectively formed on the pad 112 exposed through the opening of the solder resist layer.

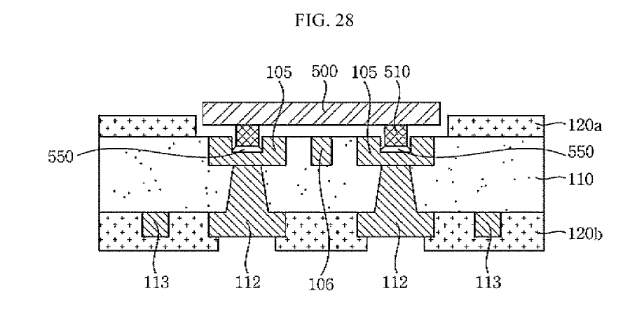

Referring to FIG. 27, an element 500 including a bumping material 550 on one end of a metal pillar bump 510 is prepared. Referring to FIG. 28, one end of the pillar bump 510 of the element 500 is inserted into the groove part 103 of the printed circuit board to mount the element on the printed circuit board.

The pillar bump 510 of the element 500 is bonded to the buried pad 105 of the printed circuit board through the bumping material 550.

The adhesion may be performed through a reflow process.

According to an embodiment of the present disclosure, as described above, when the groove part is formed on the buried pad to adhere the element through the bumping material which is disposed in the groove part, it may prevent the bumping material from being spread to an adjacent pattern area.

Thus, it may improve packaging properties during assembly without defects such as unbondings, bump cracks or the like and further high density circuits capable of fine-pitch may be implemented.

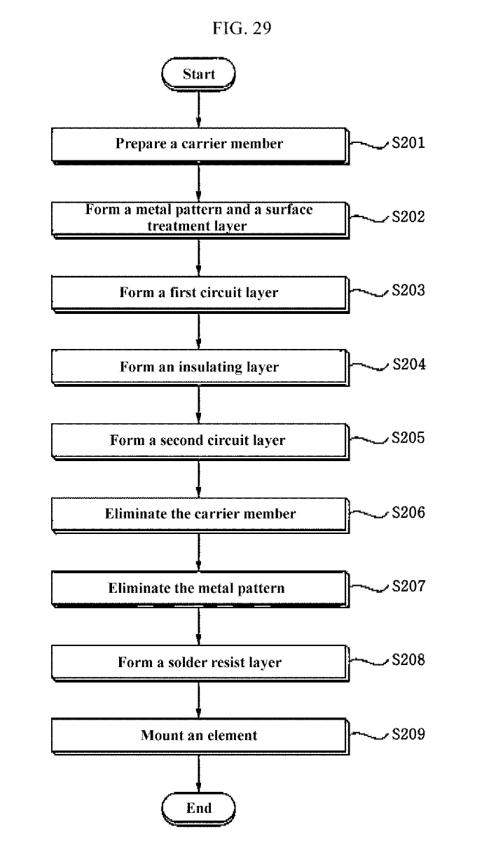

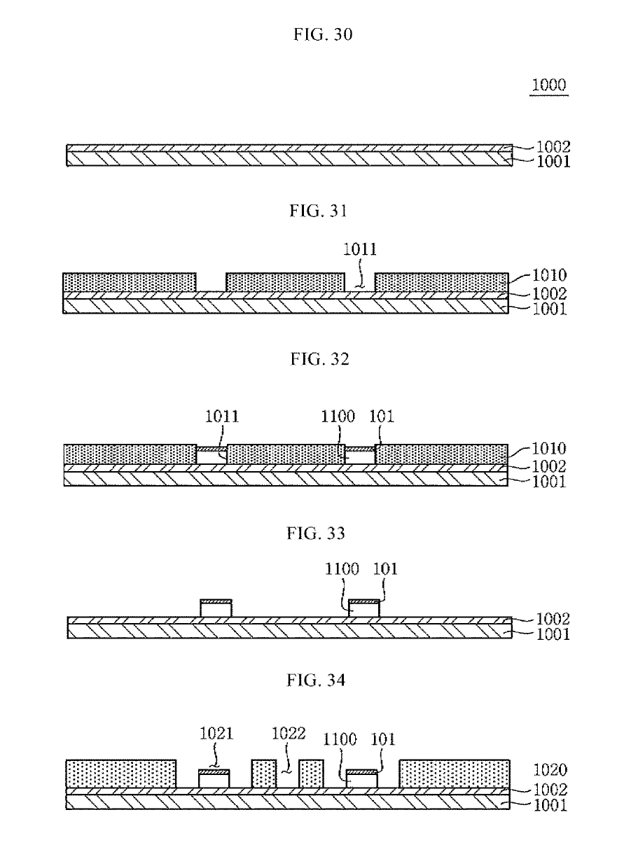

FIG. 29 is a flowchart illustrating another example of a method for manufacturing a semiconductor package. FIGS. 30 to 47 are sectional views illustrating an example of a method for manufacturing a semiconductor package in order.

Referring to FIG. 29, the method involves preparing a carrier member (S201); forming a metal pattern and a surface treatment layer (S202); forming a first circuit layer including a buried pad (S203); forming an insulating layer (S204); forming a second circuit layer (S205); eliminating the carrier member (S206); eliminating the metal pattern (S207); forming a solder resist layer (S208); and mounting an element (S209).

Hereinafter, each process will be explained with reference to sectional views illustrated in FIGS. 30 to 47.

Referring to FIG. 30, a carrier member 1000 including a first metal layer 1001 and a second metal layer 1002 is prepared.

Referring to FIG. 31, a first resist pattern 1010 having a first opening 1011 is formed on the carrier member 1000.

Referring to FIG. 32, a metal pattern 1100 and a surface treatment layer 101 are formed in order on the carrier member 1000 at the first opening 1011 through a plating process.

The plating process may be performed through immersion and/or

Docket No. 013115.0360 electrodeposition. The metal pattern 1100 may be formed in a metal plating layer such as nickel, except Cu. The surface treatment layer 101 may be composed in a plating layer such as Au/Ni, Au/Pd/Ni, Au/Pd and the like in order from the top.

Referring to FIG. 33, the resist pattern 1010 is completely removed.

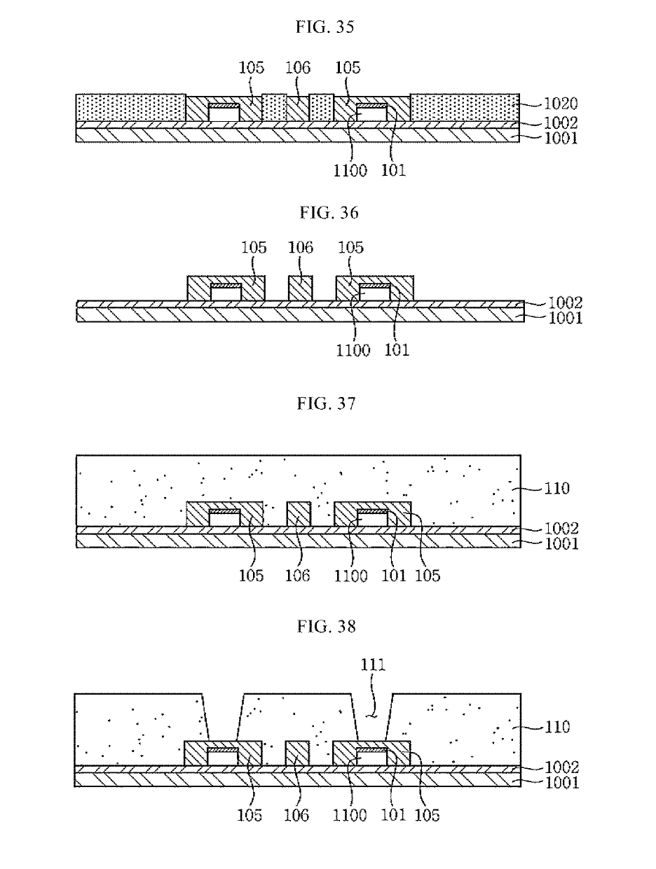

Referring to FIG. 34, a second resist pattern 1020 having second openings 1021, 1022 is formed. Referring to FIG. 35, a first circuit layer including a buried pad 105 is formed on the second openings 1021, 1022 through a plating process.

The first circuit layer includes a buried pattern 106.

Referring to FIG. 36, the second resist pattern 1020 is eliminated. Referring to FIG. 37, an insulating layer 110 is formed on the carrier member to cover the first circuit layer.

Referring to FIG. 38, a via hole 111 is formed in the insulating layer 110 using a laser drill. Even though it is not illustrated, a seed layer may be formed on the surface of the insulating layer 110 including the via hole 111 through an immersion plating process and the like after the via hole is formed.

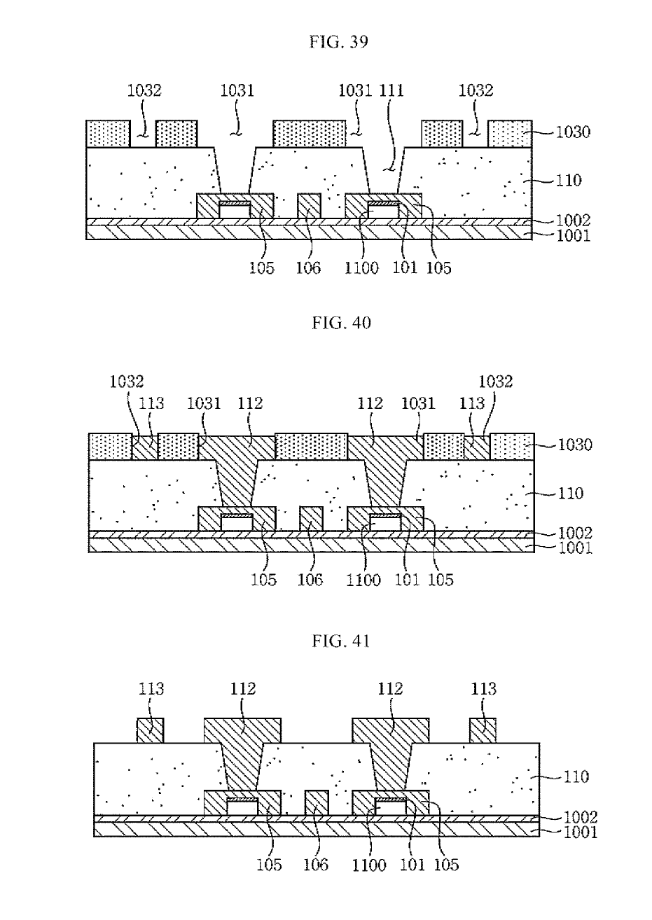

Referring to FIG. 39, a third resist pattern 1030 including third openings 1031, 1032 is formed. Referring to FIG. 40, a second circuit layer including the pad 112 is formed on the third openings 1031, 103 through a plating process.

The second circuit layer includes the circuit pattern 113.

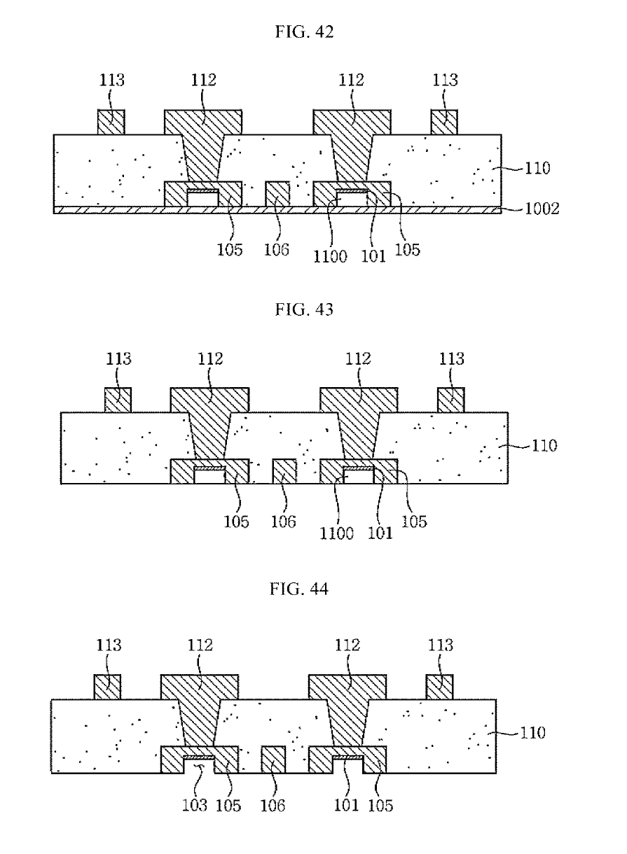

Referring to FIG. 41, the third resist pattern 1030 may be eliminated. Referring to FIGS. 42 and 43, the first metal layer 1001 and the second metal layer 1002 of the carrier member may be removed in order.

Referring to FIG. 44, the metal pattern 1100 is removed, and the groove part 103 may be formed through etching and the like.

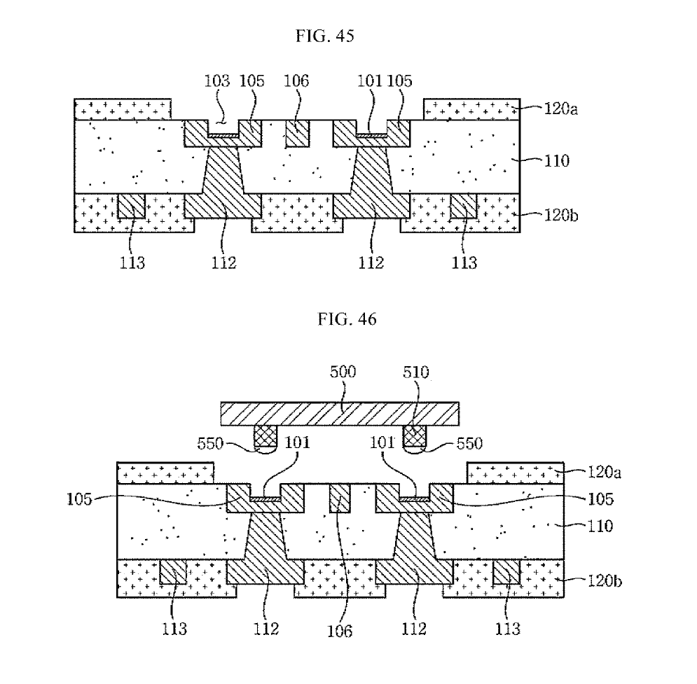

Referring to FIG. 45, solder resist layers 120a, 120b in a liquid or film type are formed as a protection layer on the outmost layer of both sides.

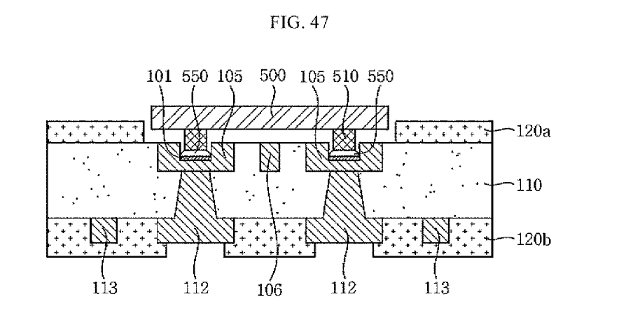

Referring to FIG. 46, an element 500 including a bumping material 550 on one end of a metal pillar bump 510 is prepared. Referring to FIG. 47, one end of the pillar bump 510 of the element 500 is inserted into the groove part 103 of the printed circuit board to mount the element 500 on the printed circuit board.

According to an example of the present disclosure, assembly of the element and the board may be implemented inside the outmost layer using the buried pad 105 including the groove part 103, such that fine bump may be provided, a bump size of the element may be minimized, design freedom may be improved, and height of overall package may be reduced due to such a bump structure. Furthermore, solder bridge issues with adjacent bumps may be minimized.

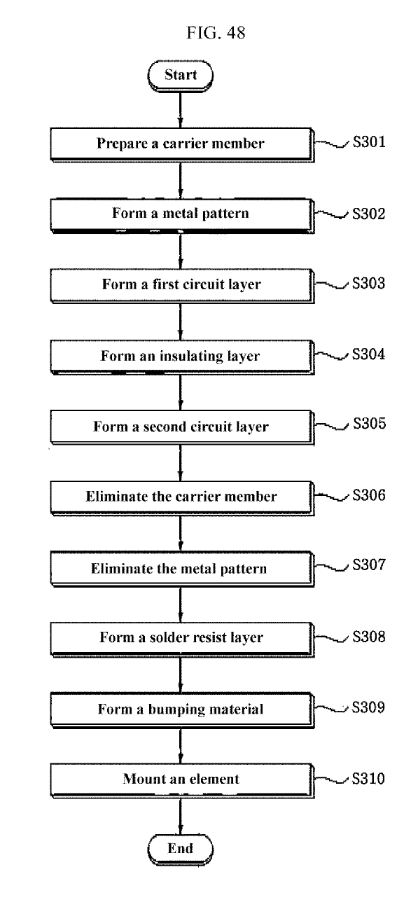

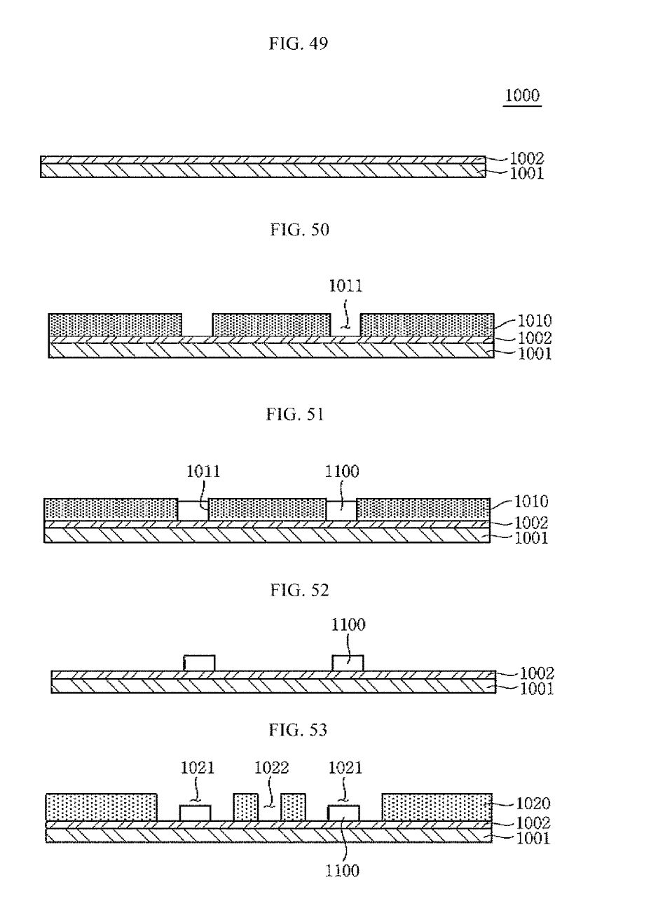

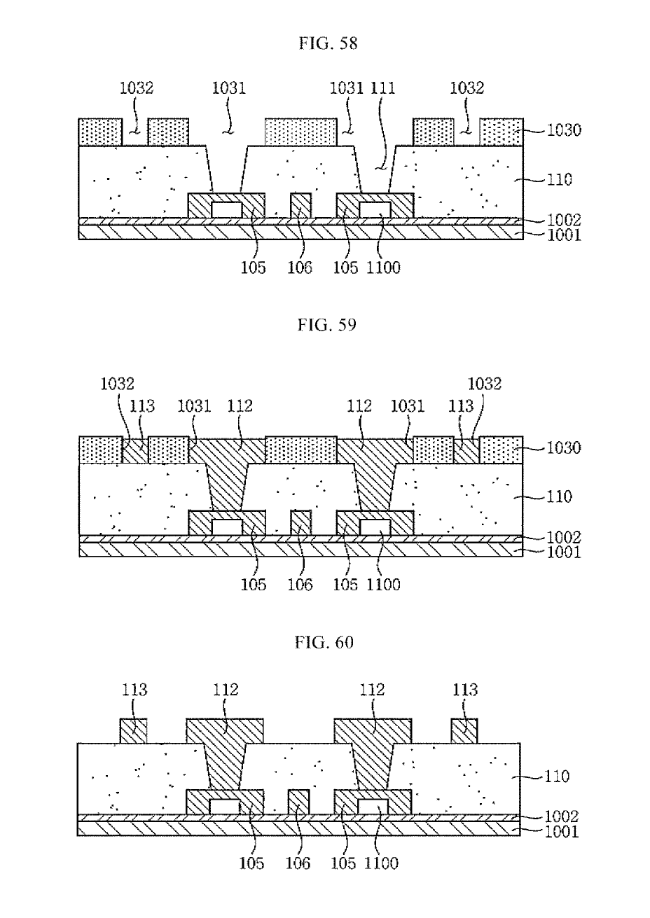

FIG. 48 is a flowchart illustrating another example of a method for manufacturing a semiconductor package. FIGS. 49 to 68 are sectional views illustrating in order an example of a method for manufacturing a semiconductor package according to FIG. 48.

Referring to FIG. 48, the method involves preparing a carrier member (S301); forming a metal pattern (S302); forming a first circuit layer including a buried pad (S303); forming an insulating layer (S304); forming a second circuit layer (S305); eliminating the carrier member (S306); eliminating the metal pattern (S307); forming a solder resist layer (S308); forming a bumping material (S309); and mounting an element (S310).

Hereinafter, each process will be explained with reference to sectional views illustrated in FIGS. 49 to 68.

Referring to FIG. 49, a carrier member 1000 including a first metal layer 1001 and a second metal layer 1002 is prepared. Referring to FIG. 50, a first resist pattern 1010 having a first opening 1011 is formed on the carrier member.

Referring to FIG. 51, a metal pattern 1100 is formed on the first opening 1011 through a plating process. Referring to FIG. 52, the resist pattern 1010 is eliminated.

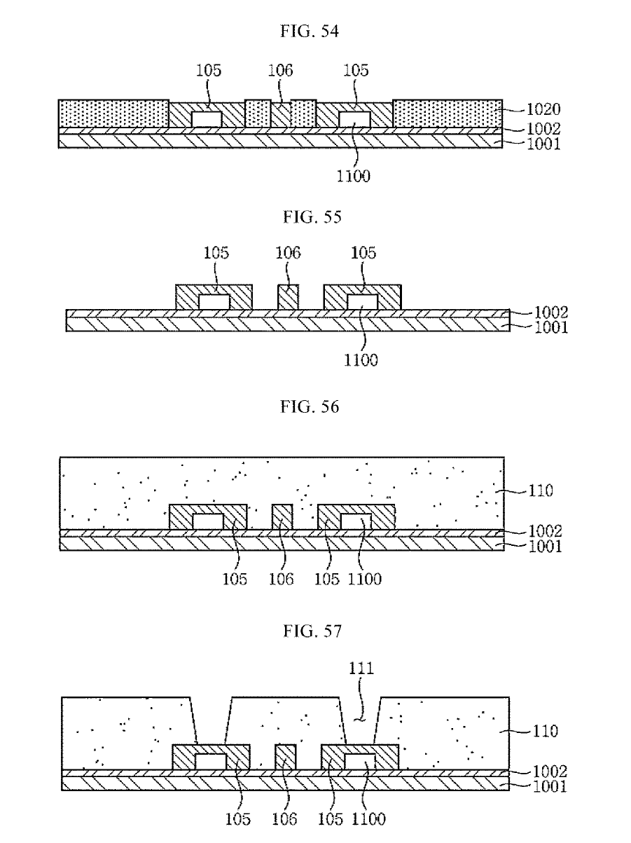

Referring to FIG. 53, a second resist pattern 1020 including second openings 1021, 1022 is formed. Referring to FIG. 54, a first circuit layer including the buried pad 105 is formed on the second openings 1021, 1022 through the plating process. Referring to FIG. 55, the second resist pattern 1020 is eliminated.

Referring to FIG. 56, an insulating layer 110 is formed on the carrier member to cover the first circuit layer. Referring to FIGS. 57 to 60, a second circuit layer is formed through SAP. The process is the same as described with reference to FIGS. 19 to 22.

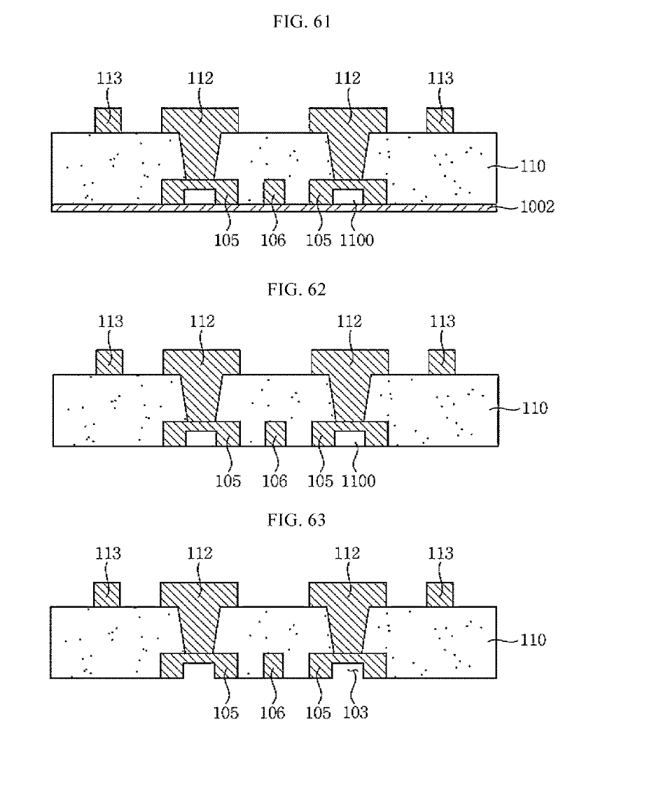

Referring to FIGS. 61 and 62, the first metal layer 1001 and the second metal layer 1002 of the carrier member are removed in order. Referring to FIG. 63, the metal pattern 1100 may be removed, and the groove part 103 is formed.

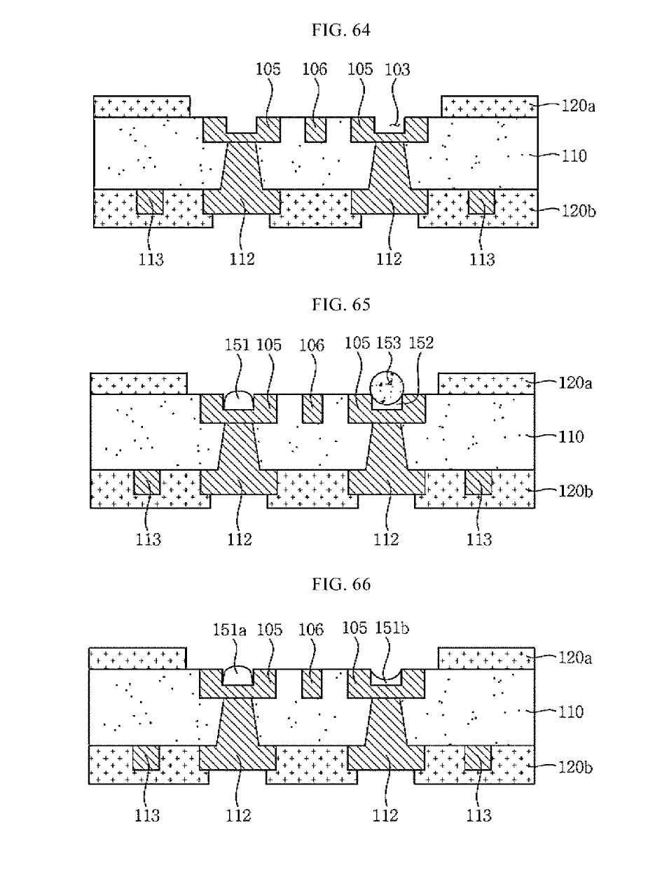

Referring to FIG. 64, solder resist layers 120a, 120b in a liquid or film type are formed as a protection layer on the outmost layer of both sides.

Referring to FIG. 65, bumping materials 151, 152, 153 are disposed in the groove part 103.

According to one example, the bumping material 151 may include solder paste.

According to another example, the bumping materials 152, 153 may include flux formed on the lower surface of the groove part 103 and a solder ball formed on the upper surface of the groove part 103.

Referring to FIG. 66, the bumping materials 151, 152, 153 are formed to have a protrusion part 151a that is protruded toward the upper part of the buried pad 105 or may be formed to have a recession part 151b that is recessed toward inside the buried pad 105 through a reflux process or a reflux and deflux process.

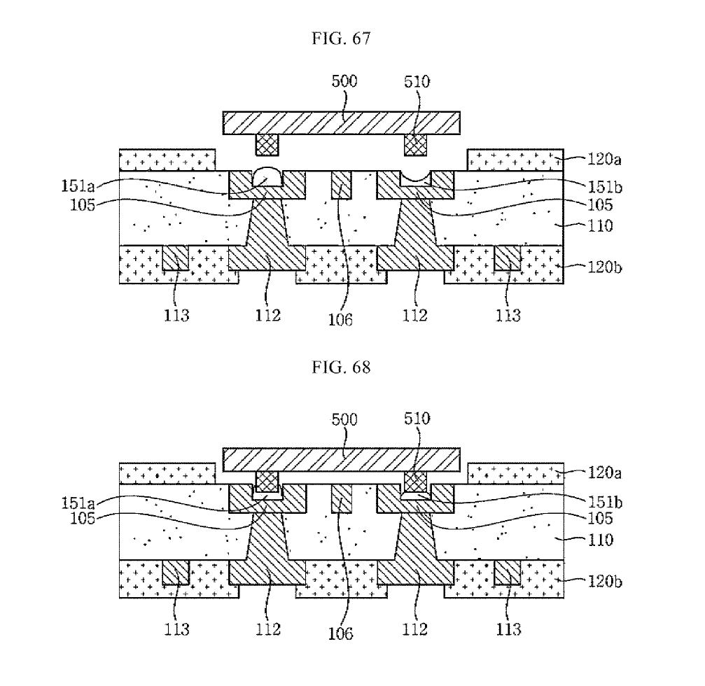

Referring to FIG. 67, an element 500 having a metal pillar bump 510 is prepare. Referring to FIG. 68, one end of the pillar bump 510 of the element 500 is inserted into the groove part 103 of the printed circuit board to mount the element 500 on the printed circuit board.

The pillar bump 510 of the element 500 is bonded to the buried pad 105 of the printed circuit board through the bumping materials 151a, 151b.

The bonding process may be performed, for example, by applying non-conductive paste at the groove part 103 to bond the element and the board through thermal compression. The thermal compression bonding may provide less thermal damage, resulting in improved reliability when it is applied to an element having a low dielectric constant, compared to the conventional reflow bonding. A peripheral bump pad method may be also used for high density circuits.

However, the reflow bonding may be also used in the present disclosure in addition to the bonding processes described above.

According to an embodiment of the present disclosure, when the groove part is formed on the buried pad to adhere the element through the bumping material which is disposed into the groove part, it may prevent the bumping material from being spread to an adjacent pattern area.

Thus, it may improve packaging properties during assembly without defects such as unbondings, bump cracks or the like and further high density circuits capable of fine-pitch may be implemented.

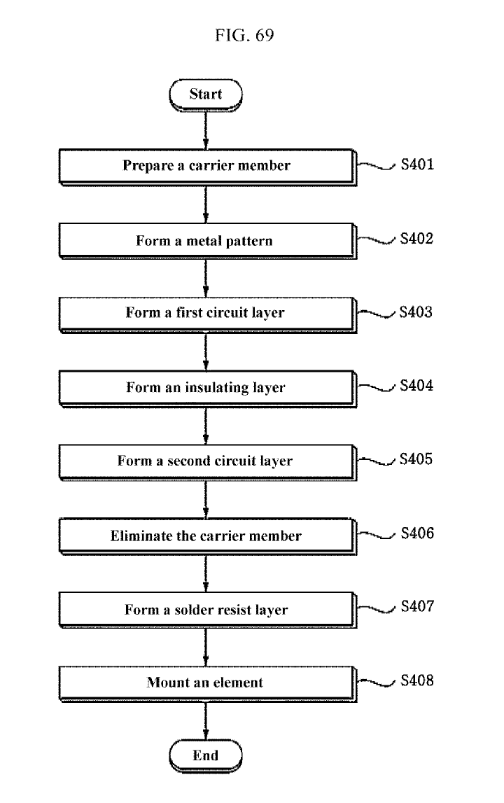

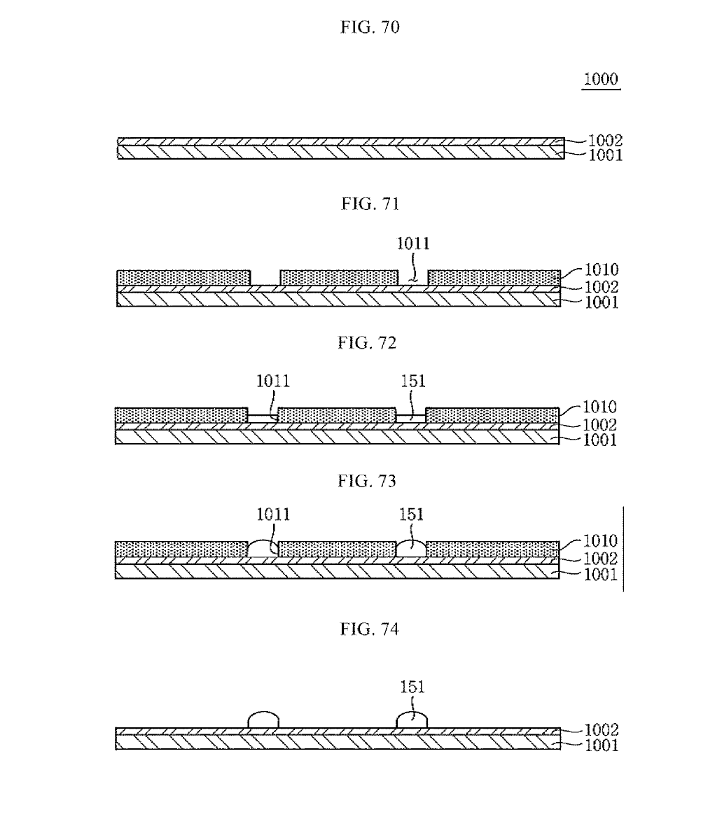

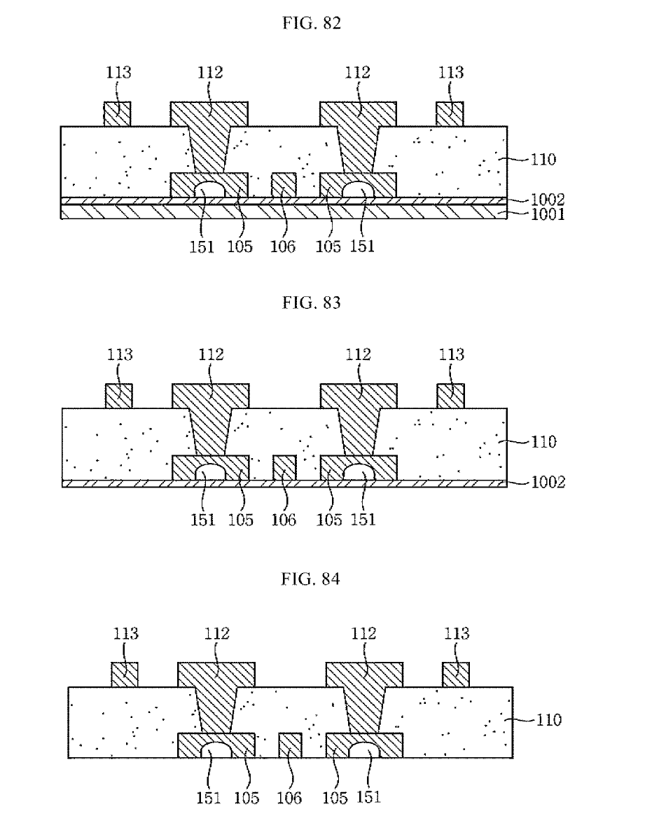

FIG. 69 is a flowchart illustrating another example of a method for manufacturing a semiconductor package. FIGS. 70 to 87 are sectional views illustrating an example of a method for manufacturing a semiconductor package according to FIG. 69 in order.

Referring to FIG. 69, the method involves preparing a carrier member (S401); forming a bumping pattern (S402); forming a first circuit layer including a buried pad (S403); forming an insulating layer (S404); forming a second circuit layer (S405); eliminating the carrier member (S406); forming a solder resist layer (S407); and mounting an element (S408).

Hereinafter, each process will be explained with reference to sectional views illustrated in FIGS. 70 to 87.

Referring to FIG. 70, a carrier member 1000 including a first metal layer 1001 and a second metal layer 1002 is prepared. Referring to FIG. 71, a first resist pattern 1010 having a first opening 1011 is formed on the carrier member 1000.

Referring to FIG. 72, a bumping material 151 is formed on the first opening 1011 through a solder paste printing process. Referring to FIG. 73, a reflow process is carried out. Referring to FIG. 74, the resist pattern 1010 is removed.

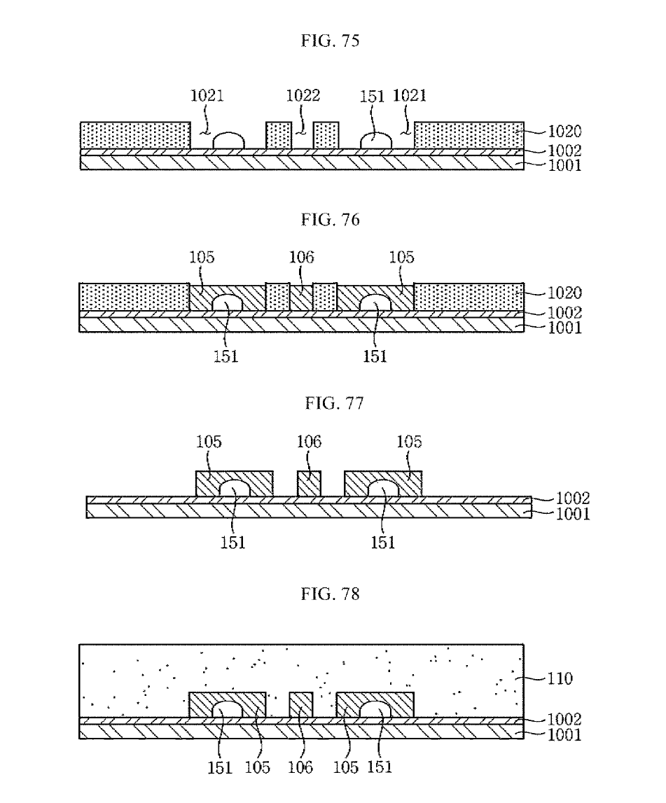

Referring to FIG. 75, a second resist pattern 1020 including second openings 1021, 1022 is formed. Referring to FIG. 76, a first circuit layer including the buried pad 105 is formed at the second openings 1021, 1022 through the plating process. Referring to FIG. 77, the second resist pattern 1020 is eliminated.

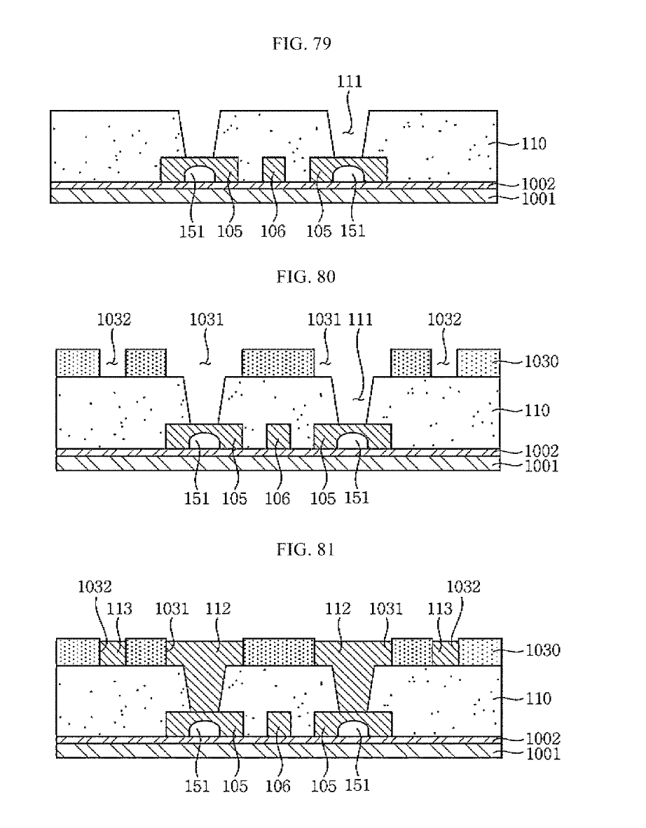

Referring to FIG. 78, an insulating layer 110 is formed on the carrier member to cover the first circuit layer. Referring to FIGS. 79 to 82, a second circuit layer is formed through the SAP. The process is the same as described above with reference to FIGS. 19 to 22.

Referring to FIGS. 83 and 84, the first metal layer 1001 and the second metal layer 1002 of the carrier member is eliminated in order.

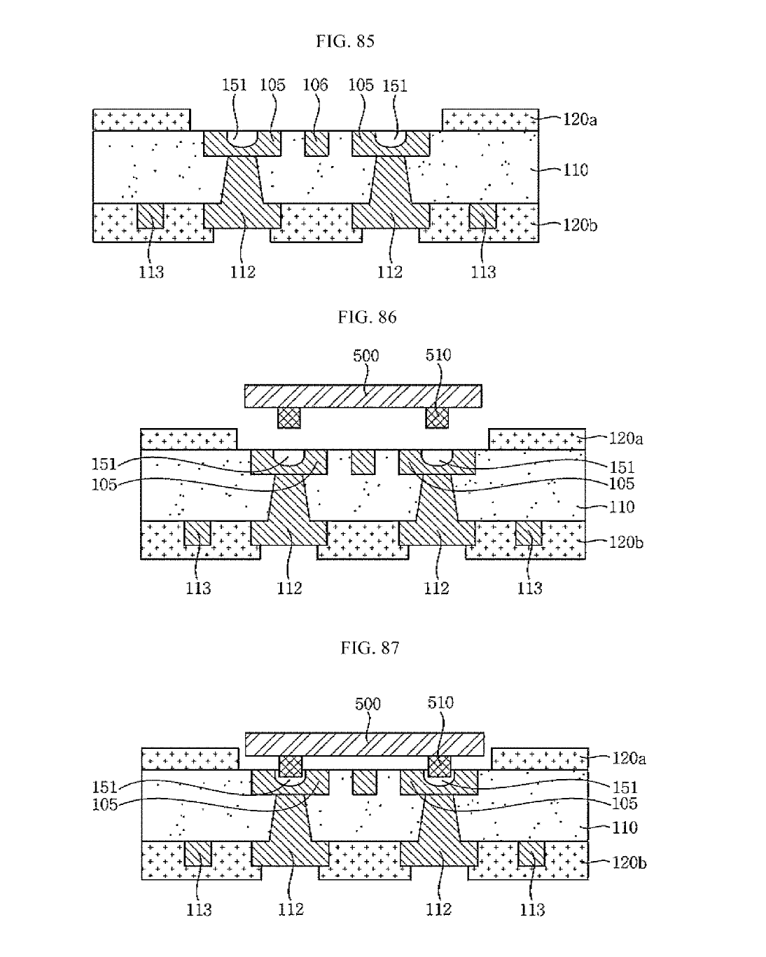

Referring to FIG. 85, solder resist layers 120a, 120b in a liquid or film type is formed as a protection layer on the outmost layer of both sides.

Referring to FIG. 86, an element 500 including a metal pillar bump 510 is prepared. Referring to FIG. 87, one end of the pillar bump 510 of the element 500 is inserted into the groove part 103 of the printed circuit board to mount the element 500 on the printed circuit board.

The pillar bump 510 of the element 500 is bonded to the buried pad 105 of the printed circuit board through the bumping material 550.

According to one example, assembly of the element and the board may be implemented inside the outmost layer using the buried pad 105 including the groove part 103, such that fine bump may be provided, a bump size of the element may be minimized, design freedom may be improved, and height of overall package may be reduced due to such a bump structure. Furthermore, solder bridge issues with adjacent bumps may be minimized.

According to one example of the printed circuit board and the method for manufacturing the same described above, it is thus possible to minimize solder bridge problems.

According to one example of the printed circuit board and the method for manufacturing the same described above, it is thus possible to implement high density circuits and to improve reliability of the printed circuit board.

According to one example of the printed circuit board and the method for manufacturing the same described above, it is thus possible to produce a semiconductor package that is able to implement fine-pitch for assemblies of an element and a printed circuit board.

According to one example of the printed circuit board and the method for manufacturing the same described above, it is thus possible to produce a semiconductor package that exhibits improved packaging properties without defects such as unbondings, bump cracks or the like.

According to one example of the printed circuit board and the method for manufacturing the same described above, it is thus possible to produce a semiconductor package while reducing the height of the entire package.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A printed circuit board comprising:
a circuit layer comprising a buried pad embedded on an upper surface of an insulating layer; and
a groove part disposed in the buried pad.

2. The printed circuit board of claim 1, further comprising a surface treatment layer disposed on a lower surface of the groove part.

3. The printed circuit board of claim 1, further comprising a bumping material disposed in the groove part.

4. The printed circuit board of claim 3, wherein the bumping material comprises solder paste.

5. The printed circuit board of claim 3, wherein the bumping material comprises a solder ball.

6. The printed circuit board of claim 3, wherein the bumping material has a protrusion part that protrudes toward an upper part of the buried pad.

7. The printed circuit board of claim 3, wherein the bumping material has a recession part that recessed toward a bottom of the buried pad.

8. The printed circuit board of claim 1, wherein the circuit layer comprises a buried pattern embedded in the upper surface of the insulating layer.

9. The printed circuit board of claim 1, wherein the circuit layer comprises a pad disposed on a lower surface of the insulating layer.

10. The printed circuit board of claim 1, further comprising a first solder resist layer formed on the upper surface of the insulating layer, except at an area where an element mounting part is disposed.

11. The printed circuit board of claim 9, further comprising a second solder resist layer disposed on the lower surface of the insulating layer, the second solder resist layer comprising an opening to expose the pad.

12. A semiconductor package comprising a circuit layer comprising
a printed circuit board comprising a circuit layer comprising a buried pad embedded in an upper surface of an insulating layer and a groove part formed on the buried pad; and
an element mounted on the printed circuit board with a pillar bump disposed in the groove part of the printed circuit board.

13. The semiconductor package of claim 12, wherein the element is mounted on the printed circuit board using a bumping material disposed in the groove part.

14. A method of manufacturing a printed circuit board comprising:
forming a metal pattern for a groove part on a carrier member;
forming a first circuit layer comprising a buried pad that surrounds the metal pattern on the carrier member;
forming an insulating layer on the carrier member to cover the first circuit layer;
forming a second circuit layer comprising a pad on the insulating layer;
removing the carrier member from a laminate on which the second circuit layer is formed; and
forming a groove part on the buried pad by removing the metal pattern.

15. The method of claim 14, further comprising forming a surface treatment layer on the metal pattern after forming a metal pattern.

16. The method of claim 14, further comprising disposing a bumping material in the groove part after the forming of the groove part.

17. A method of manufacturing a printed circuit board comprising:
forming a bumping material on a carrier member;
forming a first circuit layer comprising a buried pad that surrounds the bumping material on the carrier member;
forming an insulating layer on the carrier member to cover the first circuit layer;
forming a second circuit layer comprising a pad on the insulating layer; and
removing the carrier member from the first circuit layer and the insulating layer.

18. The method of claim 17, further comprising:
inserting a pillar bump of an element into a groove part comprising the bumping material to bond the element to the buried pad.
